(19) United States
(12) Patent Application Publication
(10) Pub. No.: US 2013/0301225 A1
(43) Pub. Date: Nov. 14, 2013

(54) CABLE MANAGEMENT APPARATUS FOR CONNECTOR

(71) Applicants: XIN-HU GONG, Shenzhen City (CN); JU-WEN DAI, Shenzhen City (CN)

(72) Inventors: XIN-HU GONG, Shenzhen City (CN); JU-WEN DAI, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/537,257

(22) Filed: Jun. 29, 2012

(30) Foreign Application Priority Data
May 11, 2012 (CN) 201210145419.7

(51) Int. Cl. H05K 7/14

(52) U.S. Cl. 361/729; 361/826

(57) ABSTRACT

A cable management apparatus includes two mounting brackets respectively fixed to opposite sides of an electronic device. A cable management arm connected between the two mounting brackets, two latch members slidably connected to the cable management arm, two resilient members connected between the cable management arm and the corresponding latch members. In addition, two releasing members rotatably mounted to the cable management arm and engaging with the corresponding latch members. Each of the mounting brackets defines two locking holes respectively adjacent to top and bottom. Each of the latch members includes a positioning pin selectively engaging in one of the locking holes of the corresponding mounting bracket to respectively lock the cable management arm is at upper or lower position. The releasing members can be rotated to drive the latch members to slide away from the corresponding mounting brackets to unlock the cable management arm relative to the mounting brackets.

### BACKGROUND

1. Technical Field

The present disclosure relates to a cable management apparatus for electronic equipment.

2. Description of Related Art

Electronic equipment, such as a server, includes a chassis and a plurality of functional modules, such as cooling modules, storage modules, and power supply modules, mounted in the chassis. The functional modules are interconnected through cables. Therefore, a cable management apparatus is fastened to a rear end of the chassis to facilitating cable management.

However, the cable management apparatus often has to be detached from the chassis when a functional module is inserted into or is removed from the chassis by the rear end of the chassis, which is inconvenient.

### BRIEF DESCRIPTION OF THE DRAWINGS

Many aspects of the present embodiments can be better understood with reference to the drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an assembled, isometric view of an embodiment of a cable management apparatus, together with an electronic device, two rails, and a rack.

FIGS. 2 and 3 are exploded views of the cable management apparatus of FIG. 1, but viewed from different perspectives.

FIG. 4 is an enlarged view of the encircled portion IV of FIG. 2.

FIG. 5 is an enlarged view of the encircled portion V of FIG. 3.

FIG. 6 is an assembled view of FIG. 3.

FIG. 7 is an enlarged view of the encircled portion VII of FIG. 6.

FIG. 8 is similar to FIG. 1, but showing the cable management apparatus at a different position.

### DETAILED DESCRIPTION

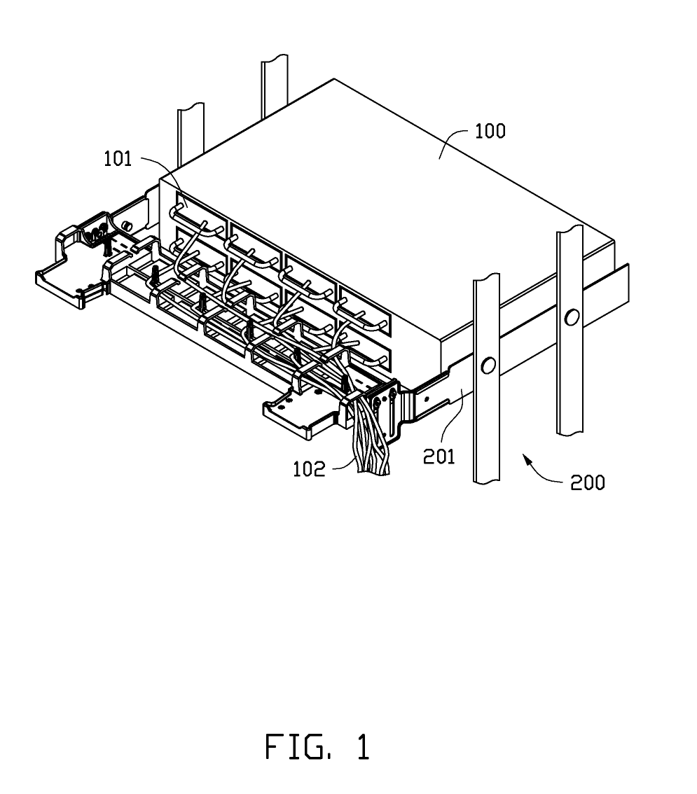

FIG. 1, is an embodiment of a cable management apparatus of the present disclosure. The cable management apparatus is mounted at a rear end of an electronic device 100, such as a server, and is attached to a rack 200 on a pair of rails 201. The electronic device 100 includes a plurality of functional modules 101, such as power supplies, data storage devices, and cooling modules, which may be withdrawn from the rear end of the electronic device 100. Cables 102 of the functional modules 101 are supported on the cable management apparatus.

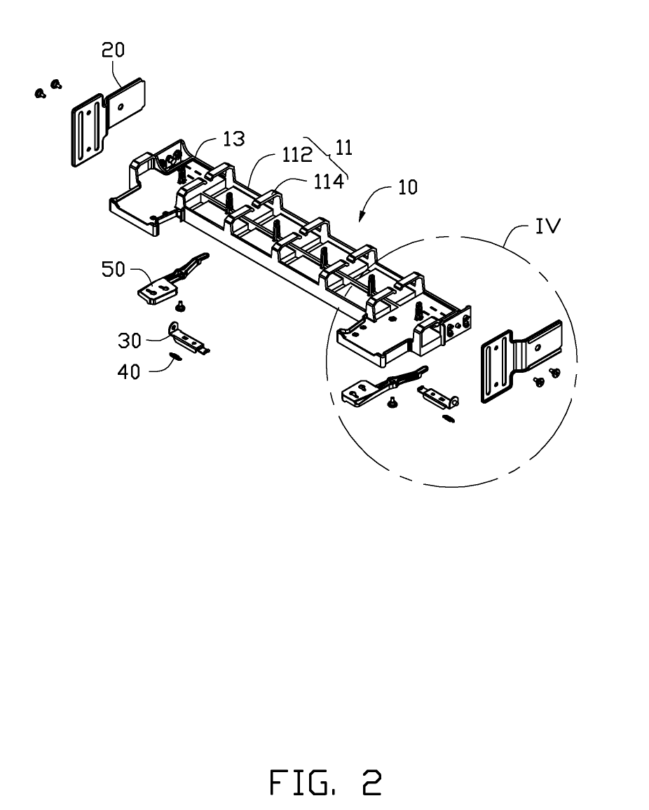

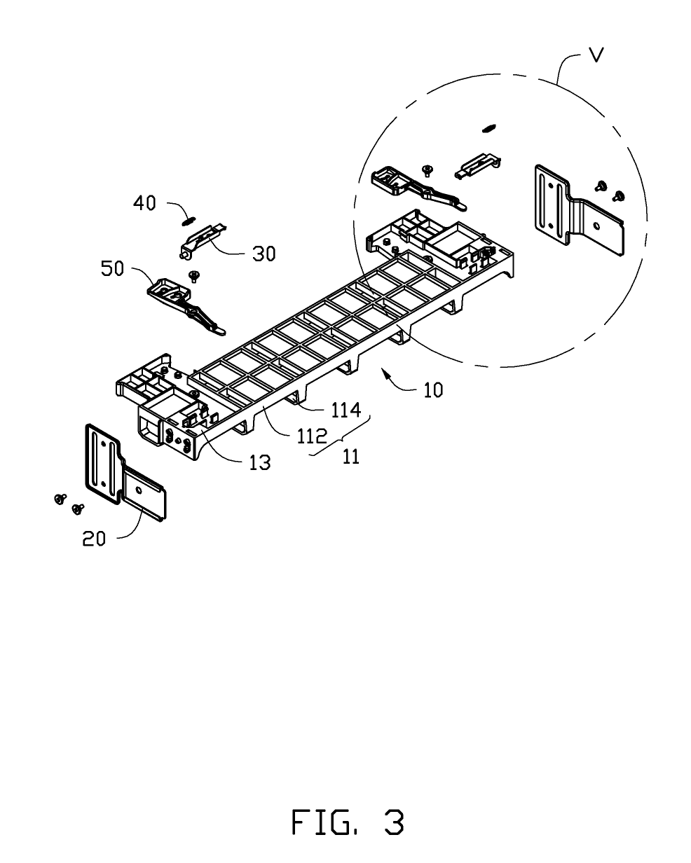

FIGS. 2 and 3, illustrates one embodiment of the cable management apparatus. The cable management apparatus includes a cable management arm 10, two mounting brackets 20, two latch members 30, two resilient members 40, and two releasing members 50.

The cable management arm 10 includes a cable holding portion 11, and two connection structures 13 respectively formed at opposite ends of the holding portion 11. The cable holding portion 11 includes a support board 112, and a plurality of substantially L-shaped cable retaining hooks 114 extending from a top of the support board 112.

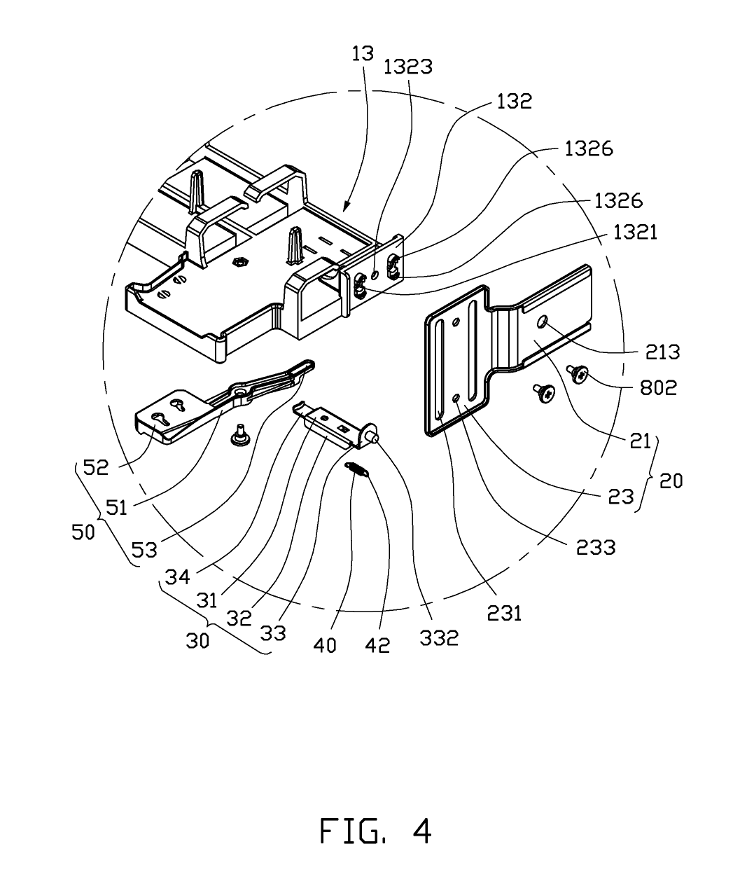

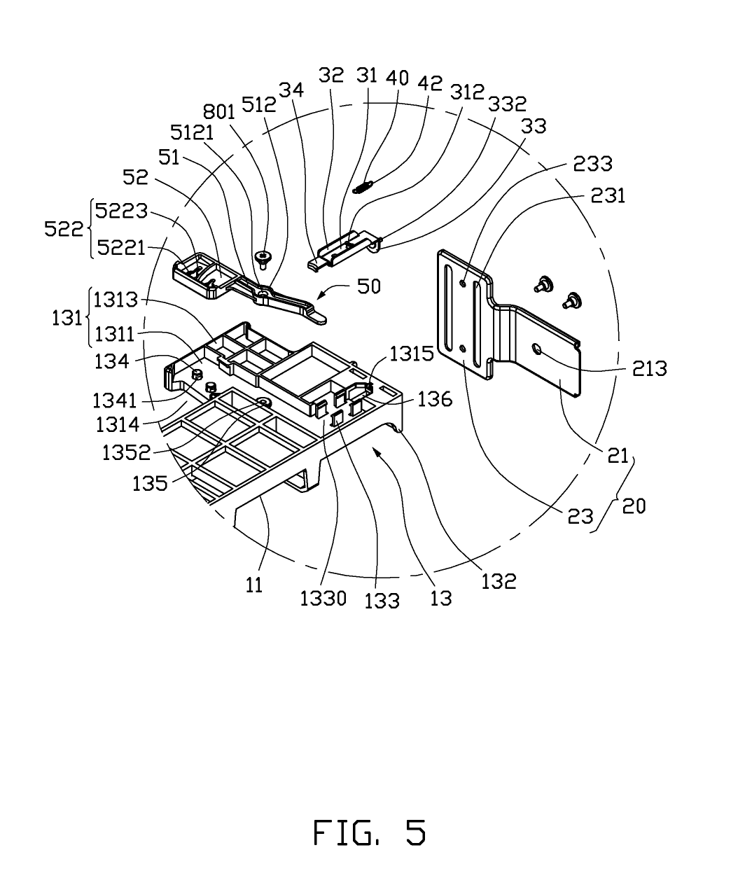

Referring to FIGS. 4 and 5, each of the connection structures 13 includes an accommodating portion 131, a locating plate 132 connected to a side of the accommodating portion 131 away from the cable holding portion 11, and a plurality of positioning tabs 133, two guiding posts 134, and a pivot seat 135 all extending down from a bottom of the accommodating portion 131.

The accommodating portion 131 includes a bottom plate 1311 and a flange 1313 perpendicularly extending down from sides of the bottom plate 1311. The flange 1313 defines an opening 1314 adjacent to the cable holding portion 11. An engagement portion 1315 is formed on the bottom of the bottom plate 1311, far away from the cable holding portion 11 and at a side of the positioning tabs 133 opposite to the cable holding portion 11.

The locating plate 132 extends up from one of the sides of the bottom plate 1311 opposite to the cable holding portion 11, and defines two securing holes 1321, and a through hole 1323 between the securing holes 1321. Two pairs of arcuate guiding tabs 1326 protrude from an outside of the locating plate 132. Two guiding tabs 1326 of each pair of guiding tabs 1326 are respectively located above and below a corresponding one of the securing holes 1321.

The positioning tabs 133 perpendicularly extend down from a bottom of the bottom plate 1311. The positioning tabs 133 are arrayed in two rows to bind a channel 1330 extending in a direction perpendicular to the locating plate 132. The bottom plate 1311 defines a slot 136 adjacent to the locating plate 132 aligning with the channel 1330.

The guiding posts 134 protrude down from the bottom of the bottom plate 1311, adjacent to the opening 1314. Each of the guiding posts 134 defines a groove 1341 in a circumference of the guiding post 134 and adjacent to the bottom plate 1311.

The pivot seat 135 protrudes down from the bottom of the bottom plate 1311, between the guiding posts 134 and the positioning tabs 133. The pivot seat 135 is columnar and axially defines a fixing hole 1352.

Each of the mounting brackets 20 includes a mounting plate 23, and a fixing plate 21 extending from a side of the mounting plate 23. The fixing plate 21 defines a fixing hole 213. The mounting plate 23 defines two parallel slide slots 231 extending along a direction parallel to the side from which the fixing plate 21 extends, and two positioning holes 233 arrayed in a direction parallel to the slide slots 231.

Each of the latch members 30 includes a rectangular sliding portion 31, two wing portions 32 perpendicularly extending down from opposite sides of the sliding portion 31. In addition, an end tab 33 perpendicularly extends up from a first end of the sliding portion 31, and a hook 34 is formed at a second end of the sliding portion 31 opposite to the end tab 33. A locating tab 312 extends from a bottom of the sliding portion 31. A locking pin 332 extends from the end tab 33, away from the sliding portion 31.

Each of the releasing members 50 includes a manipulation portion 52, a rotating arm 51 extending from a side of the manipulation portion 52, and a coupling portion 53 extending from a distal end of the rotating arm 51 opposite to the manipulation portion 52. Two round recesses 512 are respectively defined in the middle of the top and the bottom of the arm 51, overlapping with each other. A pivot hole 5121 is defined in the rotating arm 51, extending through centers of bottom walls of the recesses 512. The manipulation portion 52 defines two guide holes 522. Each guide hole 522 includes an access 5221, and an extension portion 5223 communicating with the access 5221. The access 5221 has a larger width than the extension portion 5223.

In one embodiment, each of the resilient members 40 is a coil spring including two hooks 42 formed at opposite ends of the coil spring.

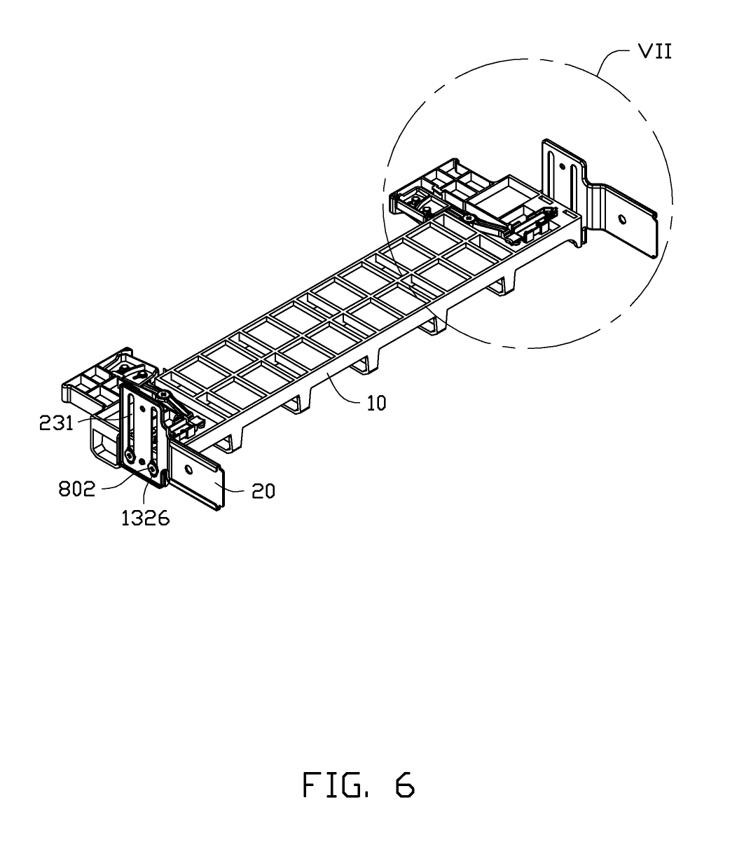

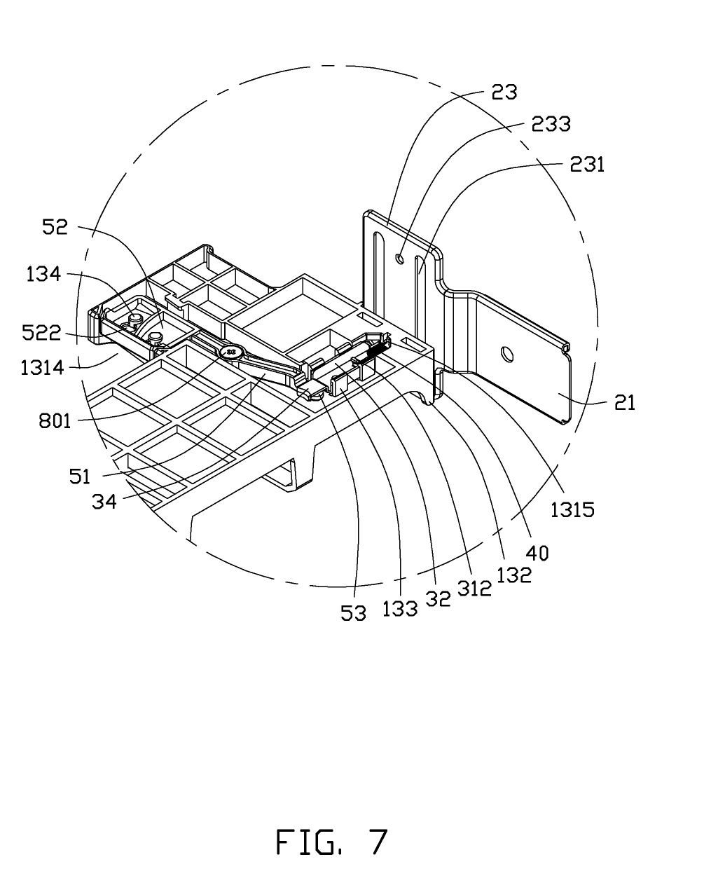

Referring to FIGS. 6 and 7, in assembly, one of the mounting brackets 20, one of the latch members 30, one of the resilient members 40, and one of the releasing members 50 are mounted to a corresponding one of the connection structures 13 of the cable management arm 10. The releasing member 50 is mounted in the accommodating portion 131 of the connection structure 13, with the pivot seat 135 engaging in the recess 512 on the top of the rotating arm 51. A fastener 801, such as a screw 801 or a rivet, extends through the pivot hole 5121 and is fastened in the fixing hole 1352 to pivotably connecting the releasing member 50 to the bottom of the connection structure 13. At the same time, the manipulation portion 52 is arranged adjacent to and accessible through the opening 1314 of the accommodating portion 131. The guiding posts 134 extend through the accesses 5221 of the corresponding guide holes 522, to enable sides defining the extension portions 5223 of the guide holes 522 to engage in the grooves 1314 with the rotating of the rotation arm 51.

The latch member 30 is received in the channel 1330. The positioning tabs 133 abut against bottom sides of the wing portions 32, to prevent the latch member 30 from accidently disengaging from channel 1330. The hook 34 of the latch member 30 engages with the bottom of the coupling portion 53 of the releasing member 50. The end tab 33 extends through the slot 136 of the bottom plate 1311, to make the locking pin 332 extend through the through hole 1323 of the locating plate 132. The hooks 42 of the resilient member 40 are respectively engaged with the engagement portion 1315 and the locating tab 312.

The mounting plate 23 of the mounting bracket 20 is attached to the locating plate 132. The two pairs of guiding tabs 1326 slidably extend through the corresponding slide slots 231. Two fasteners 802 respectively extend through the slide slots 231 and secured in the corresponding securing holes 1321, to slidably mount the mounting bracket 20 to the cable management arm 10.

Referring to FIG. 1, after the other mounting bracket 20, the other latch member 30, the other resilient member 40, and the other releasing member 50 are mounted to the other connection structure 13 of the cable management arm 10 in similar ways as aforementioned. In addition, the cable management apparatus is mounted to the rear end of the electronic device 100. Two screws extend through the fixing holes 213 of the mounting brackets 20 and are fastened to the corresponding rails 201, thereby connecting the mounting brackets 20 to the corresponding rails 201. The cable management arm 10 is slid upwards, with the fasteners 802 sliding in the corresponding slide slots 231, until the locking pins 332 of the latch members 30 align with the upper positioning holes 233. The resilient members 40 are restored, to bias the latch members 30 to move to make the locking pins 332 extend into the upper positioning holes 233. Therefore, the cable management arm 10 is fixed between the mounting bracket 20, and aligns with the functional modules 101 arranged at an upper portion of the electronic device 100.

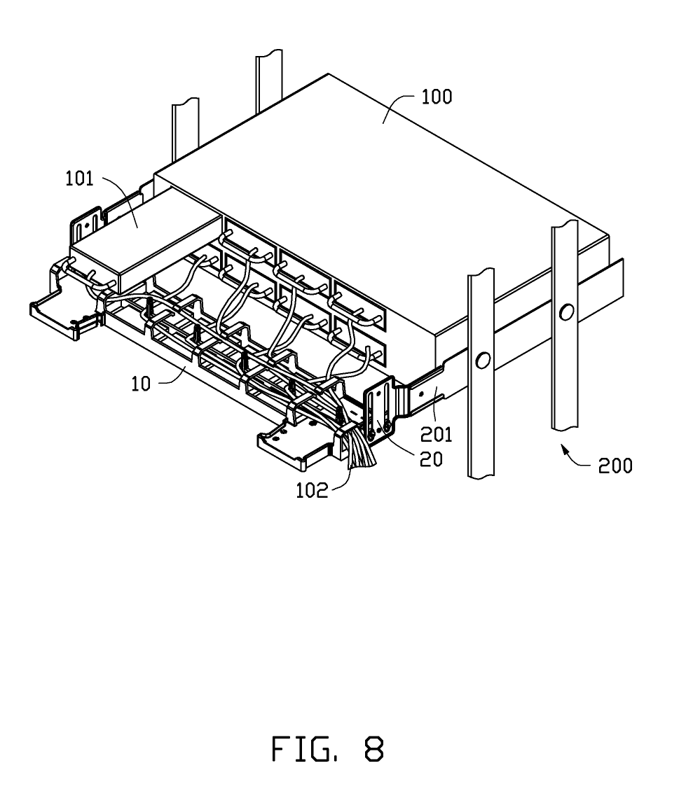

Referring to FIG. 8, when one of the functional modules 101 arranged at the upper portion of the electronic device 100 needs to be withdrawn, the releasing members 50 are rotated about the fastener 801, by manipulating the manipulation portions 52 towards the corresponding mounting brackets 20. With the rotating of the releasing members 50, the latch members 30 slide away from the corresponding mounting brackets 20 to disengage the locking pins 332 of the latch members 30 from the upper positioning holes 233 of the mounting brackets 20. The cable management arm 10 is slid downwards to misalign the locking pins 332 of the latch members 30 from the positioning holes 233 of the mounting brackets 20. The releasing members 50 are released, the resilient members 40 are restored to bias the latch members 30 to move, thereby making the locking pins 332 abut against the corresponding mounting brackets 20. The cable management arm 10 is slid down, until the locking pins 332 of the latch members 30 align with the lower positioning holes 233 of the corresponding mounting brackets 30. The resilient members 40 are restored to slide the corresponding latch members 30 outwards to make the locking pins 332 extend into the lower positioning holes 233. Therefore, the cable management arm 10 is fixed between the mounting bracket 20 again, and provides a space for withdrawing the functional module 101 arranged at an upper portion of the electronic device 100.

It is to be understood, however, that even though numerous characteristics and advantages of the present disclosure have been set forth in the foregoing description, together with details of the structure and function of the disclosure, the disclosure is illustrative only, and changes may be made in detail, especially in the matters of shape, size, and arrangement of parts within the principles of the disclosure to the full extent indicated by the broad general meaning of the terms in which the appended claims are expressed.

What is claimed is:

1. A cable management apparatus for cables of an electronic device, comprising:
two mounting brackets respectively fixed to opposite sides of the electronic device and extending out of an end of the electronic device, each of the mounting brackets defining a first positioning hole adjacent to a top of the electronic device and a second positioning hole adjacent to a bottom of the electronic device;
a cable management arm located at the end of the electronic device and mounted between the mounting brackets, and slidable between a first position adjacent to the top of the electronic device and a second position adjacent to the bottom of the electronic device;
two latch members slidably mounted to the cable management arm up and down, each of the latch members comprising a locking pin aligning with either the first positioning hole of the corresponding one of the mounting brackets when the cable management arm is at the first position, or aligning with the second positioning hole of the corresponding one of the mounting brackets when the cable management arm is at the second position;
two resilient members connected between the cable management arm and the corresponding latch members to bias the latch members to slide toward the corresponding mounting brackets, thereby making the locking pins extend into the corresponding first or second positioning holes when the cable management arm is at the first or second position; and
two releasing members rotatably connected to the cable management arm and respectively engaging with the latch members, the releasing members being operable to drive the latch member to slide away from the corresponding mounting brackets, with the corresponding resilient members deformed.

2. The cable management apparatus of claim 1, wherein each of the mounting brackets defines a vertical slide slot , the first and second positioning holes of the mounting bracket are arrayed parallel to the slide slot, the cable management arm comprises two connection structures respectively formed at opposite ends of the cable management arm, each of the connection structures comprises at least one guide block slidaby received in the slide slot of the corresponding mounting bracket.

3. The cable management apparatus of claim 2, wherein each of the connection structures defines a securing hole, the at least one guide block comprises two arcuate guide blocks respectively located above and below one of the securing holes, two fasteners extend through the slide slots of the mounting brackets and secured in the securing holes of the corresponding connection structures of the cable management arm.

4. The cable management apparatus of claim 2, wherein each of the connection structures comprises a locating plate defining a through hole, and an accommodating portion connected to a side of the locating plate, the at least one guide block of each of the connection structures protrudes from a side of the locating plate of the connection structure opposite to the accommodating portion, the latch members are mounted in the accommodating portions of the corresponding connection structures, the locking pins of the latch members extend through the through holes of the corresponding locating plate.

5. The cable management apparatus of claim 4, wherein each of the accommodating portions comprises a bottom plate, each of the connection structures further comprises a plurality of positioning tabs extending from the bottom plate of the accommodating portion, adjacent to the locating plate of the connection structure, the positioning tabs are arrayed in two rows to define a channel perpendicularly extending to the locating plate to slidably receive one of the latch members.

6. The cable management apparatus of claim 5, wherein each of the latch members comprises a sliding portion and two wing portions perpendicularly extending from opposite sides of the sliding portion to abut against the corresponding positioning tabs.

7. The cable management apparatus of claim 6, wherein each of the latch members further comprises an end tab extending from an end of the sliding portion, the locking pin of the latch member extends from the end tab.

8. The cable management apparatus of claim 4, wherein each of the accommodating portions comprises a bottom plate, each of the connection structures further comprises a pivot seat extending from the bottom plate of the accommodating portion, each of the releasing members comprises a rotating arm rotatably seated on the pivot seat of the corresponding connection structure.

9. The cable management apparatus of claim 8, wherein each of the releasing members further comprises a coupling portion extending from an end of the rotating arm, each of the latch members comprises a hook engaging with one of the releasing members.

10. The cable management apparatus of claim 9, wherein each of the releasing members further comprises a manipulation portion extending from an end of the rotating arm opposite to the coupling portion, the manipulation portion defines a guide hole, each of the connection structures further comprises a guiding post extending from the bottom plate of the accommodating portion of the connection structure to be slidably received in the guide hole of one of the releasing members.

11. A system, comprising:
a rack;
two rails attached to opposite sides of the rack;
an electronic device mounted between the rails, and comprising a first functional module adjacent to a top of the electronic equipment, and a second functional module adjacent to a bottom of the electronic equipment, each of the first and second functional modules being withdrawable from a rear end of the electronic device;
two mounting brackets respective fixed to rear ends of the rails; a cable management arm mounted between the mounting brackets and behind the electronic device, and slidable between a lower position to provide a space for withdrawing the first functional module, and an upper position to provide a space for withdrawing the second functional module.

12. The system of claim 11, wherein cables extending from the first and second functional modules are supported on the cable management arm.

13. The system of claim 12, further comprising two latch members slidably mounted to the cable management arm to engage with the corresponding mounting brackets, thereby locking the cable management arm is at the first or second positions.

14. The system of claim 12, wherein each of the mounting brackets defines a first positioning hole adjacent to a top of the mounting bracket, and a second positioning hole adjacent to a bottom of the mounting bracket, each of the latch members comprises a locking pin extending into either the first positioning hole of one of the mounting brackets to lock the cable management arm is at the first position, or the second positioning hole of the mounting bracket to lock the cable management arm is at the second position.
